(19) United States
(12) Patent Application Publication
(10) Pub. No.: US 2020/0170140 A1
(43) Pub. Date: May 28, 2020

(54) Securing Mechanism for Casing for Transporting Communications Computers and Electronics Racks

(71) Applicant: Doron Moshe, Rishon Lezion (IL)

(72) Inventor: Doron Moshe, Rishon Lezion (IL)

(21) Appl. No.: 16/686,149

(22) Filed: Nov. 17, 2019

(30) Foreign Application Priority Data
Nov. 28, 2018 (IL) 263352

(51) Int. Cl. H05K 7/18; H05K 7/14; H05K 5/00

(52) U.S. Cl. CPC H05K 7/186; H05K 5/0008; H05K 7/1489; H05K 7/1497

(57) ABSTRACT

A casing for transporting a communication rack that includes a bottom plate, four side walls, a top side and a securing mechanism for securing the communication rack to the bottom plate. The securing mechanism includes two beams and two supporting brackets. Each beam includes two holes and each end of each supporting bracket includes a piece with a threaded hole. The beams are designed to be connected to an upper side of the bottom plate and the supporting brackets are designed to be connected to two side walls of the communication rack. By that enabling to screw four screws that pass through the holes in the beams into the threaded holes in the supporting brackets for securing the communication rack to the bottom plate, and preventing the possibility to attach the side walls to the bottom plate before screwing these four screws.

### TECHNICAL FIELD The present invention relates to a securing mechanism for casings for transporting communications computers and electronics racks.

### BACKGROUND ART

Israeli patent number 246517 which is also published as PCT/IL2017/050710 describes a casing for transporting communications computers and electronics racks (“communication racks”). That casing and other casings (100) known in the art are usually includes a heavy metal bottom plate (200) on which the communication rack (300) is positioned and secured, four wooden side walls (400), and a wooden top side (500). The four side walls and the top plate are usually made of wooden plates.

Communication racks are very expensive items, very sensitive when they fall and in many cases very heavy. For example, there are communications racks of 200 cm height, 90 cm long, 60 cm wide, weighing between 200 and 2,500 kg and in a value of between One Hundred Thousands to Two million USD. Sometimes it is necessary to transport the communication rack in a standing position, and as a result it is unstable due to its weight and a relatively high center of gravity. It is customary to pack the communications racks in a wooden casing, to transport it from the manufacturer to the customer, and sometimes it is transported between countries in containers on ships.

It is known in the art that it is highly important to secure the communications racks (300) to the bottom plate (200) in order to prevent the communications racks to fall and lean on the inner side of the side walls (400) of the casings while in transport (on a sheep, track or a train). In such cases, the high weight of the communication rack and the shaking of the road may cause the side wall to collapse together with the communication rack and to causes an enormous financial damage.

The manufacturers usually use professional people for packing the communications racks and they make sure to secure them to the bottom plates. However, sometimes the customers are supposed to return the communications racks back to the manufacturers, and the customer's employees are not aware of the security importance or are not aware that the bottom plate includes elements of security, and as a result they pack the communications racks inside the casings without securing them to the heavy bottom plates. FIG. 1 depicts the casing (100) in a closed state. FIG. 2 is an exploded depiction the casing (100). FIG. 3 depicts the bottom plate (200) with a couple of securing elements (600). The communication rack is positioned between these two securing elements (600) and the professionals who pack the rack insert two screws in each side through the holes (601) into the communication rack itself and by that securing it to the bottom plate.

It is clear that there is a need for a securing mechanism in a structure that will disable the employees to forget to secure the communications racks to the bottom plates. The present invention discloses an efficient and relatively inexpensive solution to the problem mentioned above.

### DESCRIPTION OF THE DRAWINGS

The intention of the drawings attached to the application is not to limit the scope of the invention and its application. The drawings are intended only to illustrate the invention and they constitute only one of its many possible implementations.

FIG. 1 depicts the casing (100) in a closed state.

FIG. 2 is an exploded depiction the casing (100).

FIG. 3 depicts the bottom plate (200) with a couple of securing elements (600).

FIG. 4 depicts the beams (2) as connected to the bottom plate (200).

FIG. 5 depicts the beam (2) with two holes (21).

FIG. 6 depicts the supporting bracket (3).

FIG. 7 depict the communication rack (300) secured to the bottom plate (200).

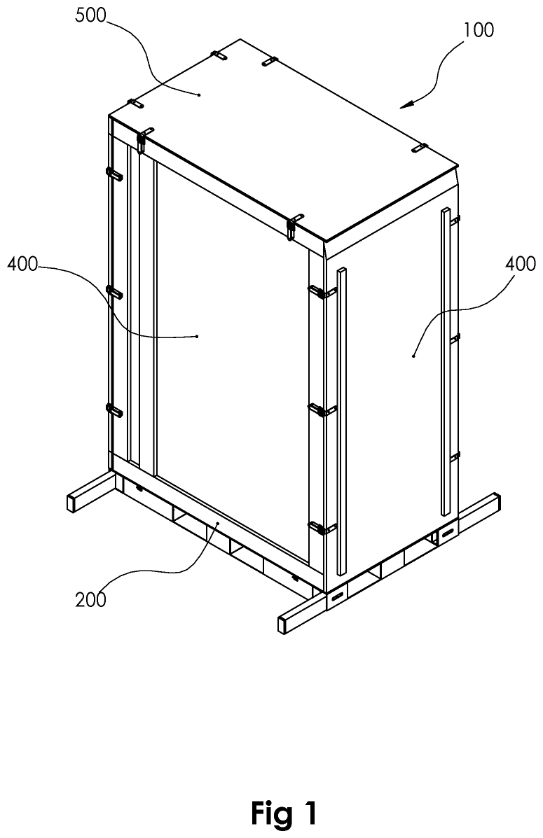

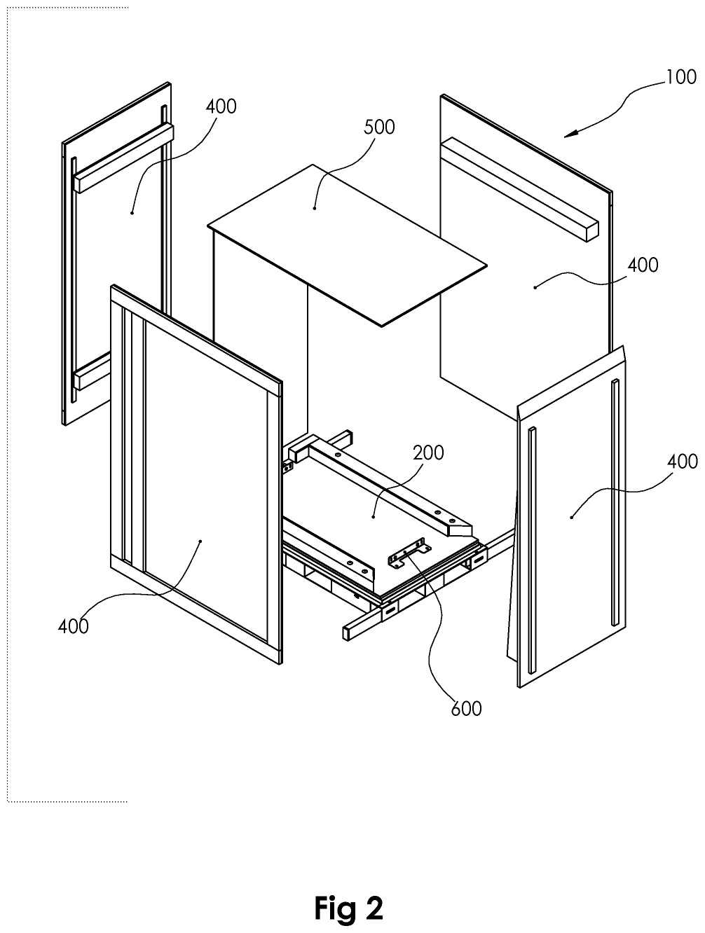

### THE INVENTION

The main objective of the present invention is to provide a casing (100) for transporting a communications rack (300) that includes a securing mechanism (1) for securing the communication rack to the bottom plate (200) of the casing. In addition, the objective of the present invention is to provide said securing mechanism (1) and a method of securing a communication rack to the bottom plate (200) of the casing (100).

The casing (100) includes a bottom plate (200) on which the communication rack (300) is positioned and secured, four side walls (400), a top side (500) and a securing mechanism (1). The four side walls (400) are usually wooden plates and together with the top and the bottom pales they create a rectangular box in which the communication rack is positioned. The bottom plate (2) is usually made of a heavy metal and the side walls (400) are aimed to be attached to its four sides for creating the rectangular box. It is preferably that the bottom plate (2) will be made of metal, and as a result it lowers the center of gravity of the casing and increases the stability of the casing.

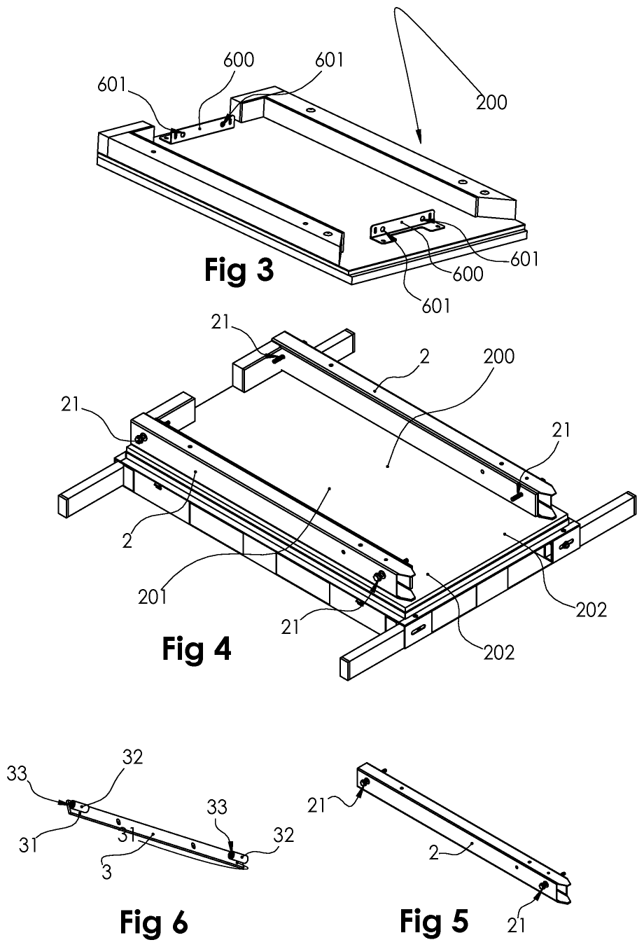

The securing mechanism (1) includes two beams (2) and two supporting brackets (3). The beams (2) are connected to the upper side (201) of the bottom plate (200) near two of its opposite margins (202). Each beam (2) includes two holes (21). The supporting brackets (3) are connected to two opposite side walls (301) of the communication rack (300) near its bottom. Each end (31) of the supporting bracket (3) includes a piece (32) with a threaded hole (33). FIG. 4 depicts the beams (2) as connected to the bottom plate (200), FIG. 5 depicts the beam (2) with two holes (21) and FIG. 6 depicts the supporting bracket (3).

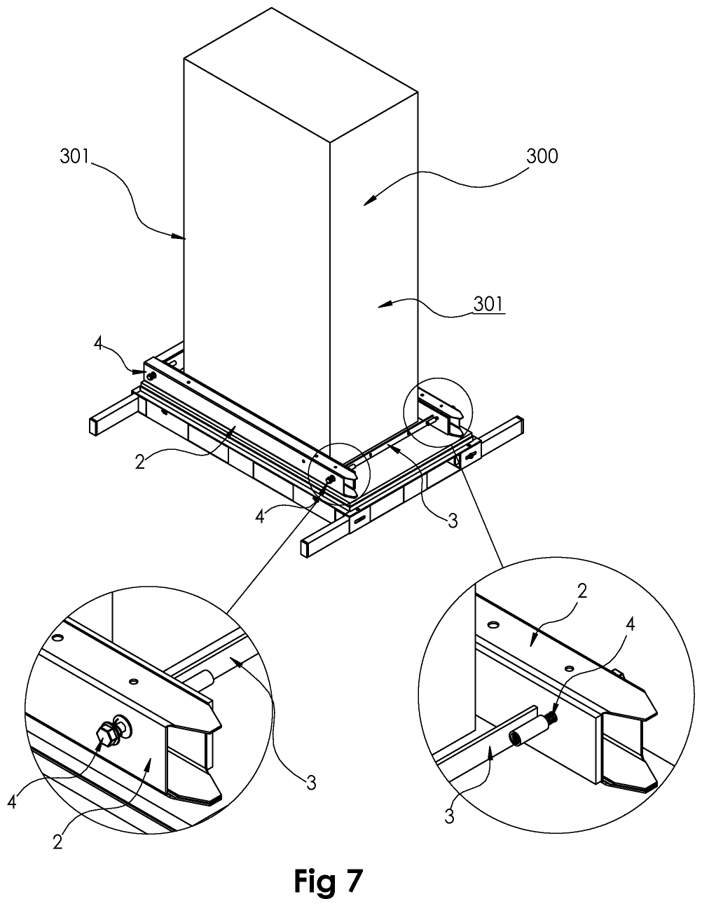

After positioning the communication rack (300) on the bottom plate (200) between the beams (2) the user that pack the communication rack (300) inside the casing (100) screw four screws (4) that pass through the holes (21) in the beams (2) into the threaded hole (33) in the supporting bracket (3) as depicted for example in FIG. 7. It is understood that the supporting brackets (3) should be attached to the communication rack (300) in a way that their threaded hole (33) will face the holes (21) of the beams (2).

The four screws (4) are supposed to be inserted into the holes (21) of the beams (2) and to remain there permanently, possibly by a spring and a ring that will prevent their removal from the beams by mistake. When the communication rack is placed on the bottom plate (200) between the two beams (2), the four screws (4) are pushed out and prevent the user from attaching at least two of the side walls (400) to the bottom plate (200), but only after the user screws the four screws (4) into the threaded hole (33) in the supporting bracket (3). In this way, even a person who did not receive instructions on the casing (100) will understands that these four screws (4) must be screwed into the supporting bracket (3) and in any way he or she will be disable to pack the rack without screwing these four screws and securing the rack to the bottom plate.

The present patent application also refers to the method for securing the communication rack to the bottom plate (200) of the casing (100) that includes the following steps and components: Providing the securing mechanism (1), connecting the beams (2) to the upper side (201) of the bottom plate (200) and connecting the supporting brackets (3) to two side walls (301) of the communication rack (300).

What is claimed is:

1. A casing for transporting a communication rack, comprising: a bottom plate, four side walls, a top side and a securing mechanism for securing the communication rack to the bottom plate;
wherein the securing mechanism includes two beams and two supporting brackets; wherein each beam includes two holes and wherein each end of each supporting bracket includes a piece with a threaded hole;
wherein said beams are designed to be connected to an upper side of the bottom plate and wherein said supporting brackets are designed to be connected to two side walls of the communication rack;
whereby enabling to screw four screws that pass through the holes in the beams into the threaded holes in the supporting brackets for securing the communication rack to the bottom plate, and preventing the possibility to attach said side walls to the bottom plate before screwing these four screws.

2. A securing mechanism for securing a communication rack to a bottom plate of a casing for transporting communications racks, comprising: two beams and two supporting brackets, wherein each beam includes two holes and each end of each supporting bracket includes a piece with a threaded hole;
wherein said beams are designed to be connected to an upper side of said bottom plate and wherein said supporting brackets are designed to be connected to two side walls of the communication rack;
whereby enabling to screw four screws that pass through the holes in the beams into the threaded holes in the supporting brackets for securing the communication rack to the bottom plate, and preventing the possibility to attach said side walls to the bottom plate before screwing these four screws.

3. A method for securing a communication rack to a bottom plate of a casing for transporting communications racks, comprising:
providing a securing mechanism for securing said communication rack to said bottom plate, said securing mechanism includes two beams and two supporting brackets, wherein each beam includes two holes and each end of each supporting bracket includes a piece with a threaded hole;
connecting said beams to an upper side of said bottom plate and connecting said supporting brackets to two side walls of the communication rack;
whereby enabling to screw four screws that pass through the holes in the beams into the threaded holes in the supporting brackets for securing the communication rack to the bottom plate, and preventing the possibility to attach said side walls to the bottom plate before screwing these four screws.
